(19) United States
(12) Patent Application Publication
(10) Pub. No.: US 2012/0212154 A1
(43) Pub. Date: Aug. 23, 2012

(54) CIRCUIT MODULE DEVICE WITH ADDRESSES GENERATED BY METHOD OF DIVIDED VOLTAGE

(76) Inventors: Lin Cheng-Lung, Jhubei City (TW); Lin Che-Chuan, Jhubei City (TW)

(21) Appl. No.: 13/032,750

(22) Filed: Feb. 23, 2011

(51) Int. Cl. H05B 37/02; G11C 5/14

(52) U.S. Cl. 315/312; 327/530

(57) ABSTRACT

A circuit module device with addresses generated by a method of divided voltage, in particular a specific circuit module device that is able to connect a plurality of circuit modules having various resistances with varied divided voltage and under this circumstance, it will be able to utilize various resistances with varied voltage values to create various specific addresses for the circuit modules thereof

### BACKGROUND OF THE INVENTION

1. Field of the Invention

The present invention relates generally to a kind of circuit module device with addresses generated by method of divided voltage, and more specifically it relates to a specific circuit module device that is able to connect a plurality of circuit modules having various resistances with varied divided voltage and under this circumstance, it will be able to utilize various resistances with varied voltage values to create various specific addresses for the said circuit modules thereof

2. The Prior Art

The known LED lamp has several features, such as high illuminating efficiency, long service life and low power consumption etc., therefore, LED lamps have already dramatically replaced traditional light bulbs in recent years, and meanwhile it has been widely applied to various decorative light string markets. FIG. 1 is a schematic view showing a known LED lamp module, wherein, it comprises red light-emitting diode 11, green light-emitting diode 12, blue light-emitting diode 13, control unit 14, LED lamp module 15 and input end of sync signal 16 etc. The known LED lamp module 15 consists of red light-emitting diode 11, green light-emitting diode 12, blue light-emitting diode 13 and control unit 14. Whereby, control unit 14 is being electrically connected with red light-emitting diode 11, green light-emitting diode 12 and blue light-emitting diode 13 respectively, which can independently control and make each light-emitting diode illuinating, flashing, selecting color combinations or changing colors respectively. Additionally, the control unit 14 is being further electrically connected to the input end of sync signal 16 in order to control the operation of light-emitting diode 11, 12, or 13 while responding to the sync signals received by the signal input of sync signal 16.

Upon the application for light strings, a plurality of known LED lamps 15 are cascaded all together, in which, the input end of sync signal 16 of each LED lamp module 15 is being connected to the control center, so that the control center will be able to control and make each LED lamp module 15 illuminating, flashing or changing colors while transferring sync control signals to input end of sync signal 16 of the said LED lamp module 15. However, the above-mentioned operational mode only can control the light strings consisting of the known LED lamp module 15 to operate synchronously, and it is impossible to addressing control the operation of each individual LED lamp module 15 to execute the special effects, such as marquee or specific arrangement of texts and images for meeting special requirement.

Since the known LED lamp module 15 does not have any dynamically address-generating function, therefore, once an operator is trying to address each LED lamp module 15, the said operator must pre-write each specific address into each corresponding LED lamp module 15 respectively, so that it is able to successfully control each individual LED lamp module 15 with pre-write address. However, there seems to be a lack of flexibility while using pre-write addresses to configure relevant circuit modules and moreover, it is impossible to change the pre-write addresses to meet the future needs. Furthermore, when it is being applied to light strings, the control center will be unable to accurately control each LED lamp module 15 unless it can record the corresponding information related to the location and address allocated for each LED lamp module 15 in advance, and under this circumstance, not only the relevant operations will become more complicated, but also it has to raise a lot of hardware costs in addition to extra memory spaces.***

The disadvantages of the known technique are as follows:

1. The known LED lamp module does not have any dynamically address-generating function;

2. The known LED lamp module seems to be a lack of flexibility while using pre-write addresses to control each individual circuit module; and

3. Whenever the known LED lamp module is being applied to light strings, its control center must record the corresponding information related to the location and address allocated for each LED lamp module, so that it must waste a lot of money on hardware costs due to a complicated allocation operation and extra memory spaces.

Thus, how to improve above-mentioned disadvantages of the known technique to make LED lamp module having a dynamically address-generating function seems to be a major concern for the present invention.

### SUMMARY OF THE INVENTION

The purpose of the present invention lies in providing a novel and advanced circuit module device with addresses generated by method of divided voltage, in which, a plurality of resistances are being electrically connected all together in series, and also the ADC input ends of a plurality of circuit modules are being electrically connected to the corresponding a plurality resistances so as to make an area between the ADC input ends of two adjacent circuit modules being electrically connected with one resistance, and in this way, it will be able to create different voltage value for each individual ADC input end of each circuit module, and furthermore, having an effect of specific voltage divided by the resistance, it will, therefore, sucessfully allocate varied addresses for a plurality of said circuit modules by using varied voltage values created thereto.

In order to fulfill the above specific purposes, hence, the present invention presents a kind of circuit module device with address generated by method of divided voltage, which comprises:

A plurality of resistances, which are being electrically connected all together in series;

A plurality of circuit modules, in which, each circuit module comprises one control unit and one Analog-to-Digital Converter (ADC); and thereat, the said control unit is being electrically connected to the said ADC, and the said ADC contains one Analog-to-Digital Converter (ADC) input end; and moreover, the ADC input ends of a plurality of said circuit modules are being electrically connected to the corresponding a plurality said resistances so as to make an area between the ADC input ends of two adjacent circuit modules being electrically connected with one resistance;

Wherein, a plurality of said circuit modules comprise at least one primary circuit module, one secondary circuit module and one third circuit module; also a plurality of said resistances comprise at least one primary resistance and one secondary resistance; and thereat, the said primary resistance is connected to the said secondary resistance in series, also the said primary resistance is being electrically connected to a position between the ADC input ends of the said primary circuit module and the said secondary circuit module; and the secondary resistance is being electrically connected to a position between the ADC input ends of the said secondary circuit module and the said third circuit module; and thereby, the said primary circuit module, the said secondary circuit module and the said third circuit module is able to convert, via Analog-to-Digital Converter (ADC), individual voltage value on the ADC input end into digital signal respectively, and in addition, while corresponding to different voltage value of said digital signal, while corresponding to different voltage value of said digital signal, the control unit of the said primary circuit module, the said secondary circuit module and the said third circuit module will generate different addresses and thus it will sucessfully complete the addressing operation for a plurality of said circuit modules accordingly.

A circuit module device with addresses generated by method of divided voltage as defined in the preceding paragraphs, in which, each circuit module of a plurality of said circuit modules further comprises one memory unit, and all relevant addresses generated by the control unit of each circuit module will be stored in the said memory.

A circuit module device with addresses generated by method of divided voltage as defined in the preceding paragraphs, in which, it further contains one grounding being electrically connected to the ADC input end of the said primary circuit module.

A circuit module device with addresses generated by method of divided voltage as defined in the preceding paragraphs, in which, each circuit module of a plurality of said circuit modules further comprises one signal input end, and thereat, the signal input ends of a plurality of said circuit modules are being electrically connected all together; moreover, one addressing command can be transferred to a plurality of said circuit modules through the said signal input end to drive as well as control the addressing operation executed by a plurality of said circuit modules.

A circuit module device with addresses generated by method of divided voltage as defined in the preceding paragraphs, in which, a plurality of said circuit modules are a plurality of LED lamp modules.

A circuit module device with addresses generated by method of divided voltage as defined in the preceding paragraphs, wherein, each LED lamp module of a plurality of said LED lamp modules comprises one red light-emitting diode, one green light-emitting diode and one blue light-emitting diode, and also the said control unit is being electrically connected to the said red light-emitting diode, the said green light-emitting diode and the said blue light-emitting diode respectively, so that it will be able to control either the said red light-emitting diode, the said green light-emitting diode or the said blue light-emitting diode making it illuminating, flashing or changing colors.

### BRIEF DESCRIPTION OF THE DRAWING

The present invention will be apparent to those skilled in the art by reading the following detailed description of a preferred embodiment thereof, with reference to the attached drawings, in which:

FIG. 1 is a schematic view showing a known LED lamp module;

FIG. 2 is a schematic view showing a preferred embodiment of circuit module device with addresses generated by method of divided voltage in accordance with the present invention; and

FIG. 3 is a schematic view showing another preferred embodiment of circuit module device with addresses generated by method of divided voltage, which is being applied to LED lamp module, in accordance with the present invention.

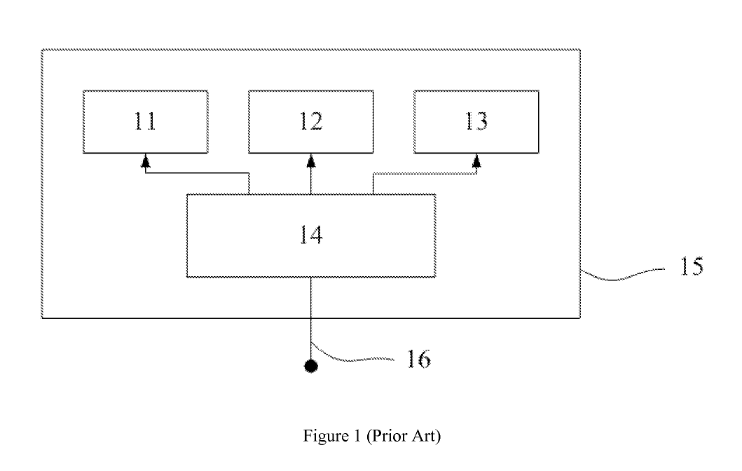

### DETAILED DESCRIPTION OF THE PREFERRED EMBODIMENT

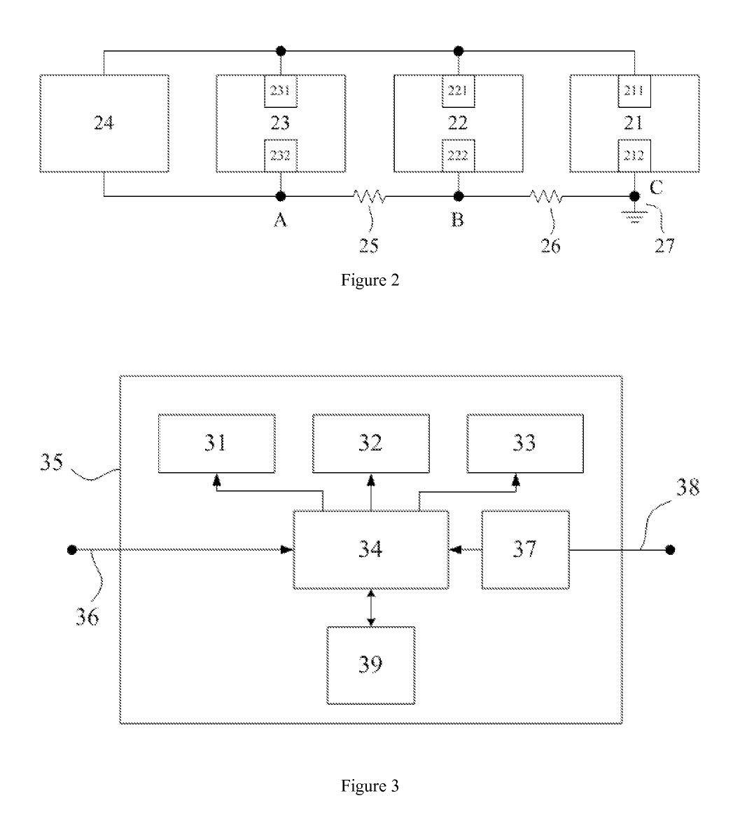

FIG. 2 is a schematic view showing a preferred embodiment of circuit module device with addresses generated by method of divided voltage in accordance with the present invention, wherein, it comprises the circuit module 21, 22, 23, signal input end 211, 221, 231, Analog-to-Digital Converter (ADC) 212, 222, 232, control center 24, resistance 25, 26 and grounding 27 etc. The circuit module 21 (22 or 23) contains the control unit, signal input to end 211 (221 or 231) and Analog-to-Digital Converter (ADC) 212 (222 or 232), and also the control center of each circuit module 21 (22 or 23) is being electrically connected to the signal input end 211 (221 or 231) as well as ADC 212 (222 or 232). The signal input ends 211, 221 and 231 of circuit modules 21, 22 and 23 are being electrically connected all together and also they are being further connected to the control center 24. There is an extra ADC input end being installed on ADC 212, 212, 222 of each circuit module 21, 22, 23 respectively. Both the resistances 25 and 26 are being connected in series, and the resistance 25 is being electricity connected to an area between the input end of ADC 222 and the input end of ADC 232; moreover, the resistance 26 is being electricity connected to an area between the input end of ADC 212 and the input end of ADC 222. Additionally, at one end where the resistance 26 being connected to the input end of ADC 212, it is being electrically connected to the grounding 27; and thereat, at one end where the resistance 25 being connected to the input end of ADC 232, it is being electrically connected to the control center 24.

When there is one voltage being output from one end of the control center 24 connected with the resistances 25, the said output voltage will create a voltage drop at the resistance 25 and 26 and hence contributing varied voltage value to Point A, B or C. Consequently, when circuit module 23, 22, 21 is trying to detect the voltage value on the input end through ADC 232, 222, 212, it will easily obtain varied voltage value from Point A, B or C respectively, and in addition, while converting the analog voltage values detected by the said ADC 232, 222, 212 into digital signals, the control unit will correspond to the varied voltage values contained in the said digital signals and generate different addresses for relevant circuit module accordingly. For example: when resistance 25 and 26 has a same resistance value, supposed the voltage value output from the control center 24 is 2V, then relative voltage value applied on Point A, B or C will be 2V, 1V or 0V respectively. Therefore, ADC 232, 222, 212 will convert the analog voltage value of 2V, 1V and 0V into corresponding digital signal so as to make each individual control unit of the circuit module 23, 22, 21 creating different address 2, 1 and 0 respectively. Thus, after the completion of addressing operation, the said control center 24 will be able to further control the illuminating effects of specific circuit module just by simply adding the address information into each control signal.

Certainly, it is allowable to make the control center 24 outputting varied voltage values, also to adopt different resistance values for the resistance 25 and 26 resistivity, and instead, at one end of resistance 26 that is being connected to one end of ADC 212 originally. Besides, it is allowable to increase more units of circuit modules as well as the corresponding resistances.

On the other hand, the control center 24 is able to send out the specific addressing command from one end connected with the signal input end 211, 221, 231 in order to drive the circuit module 21, 22 and 23 to execute the addressing operation synchronously.

FIG. 3 is a schematic view showing another preferred embodiment of circuit module device with addresses generated by method of divided voltage, which is being applied to LED lamp module, in accordance with the present invention, in which, it comprises the red light-emitting diode 31, green light-emitting diode 32, blue light-emitting diode 33, control unit 34, LED lamp module 35, signal input end 36, ADC 37, ADC input end 38 and memory unit 39 etc. The circuit module provided by the present invention can be LED lamp module 35, wherein, the said LED lamp module 35 consists of red light-emitting diode 31, green light-emitting diode 32, blue light-emitting diode 33, control unit 34, signal input end 36, ADC 37 and memory unit 39 etc. And the control unit 34 is being electrically connected to the red light-emitting diode 31, green light-emitting diode 32, blue light-emitting diode 33, signal input end 36, ADC 37 as well as memory unit 39 respectively, and thereat, it can independently control each light-emitting diode to make it illuminating, flashing or changing colors. In addition, as described in preceding paragraphs, the ADC 37 is able to convert the voltage value on the ADC input end 38 into digital signal and then delivering it to the said control unit 34, so that the said control unit 34 will correspond to the said digital signal to create corresponding address which will be stored in the memory unit 39 later.

When it is being applied to light strings, it is allowable to directly give one addressing command to signal input end 36 of LED lamp module 35 to drive all LED lamp modules generating specific addresses automatically. Since the addresses generated by the said LED lamp module 35 has a direct relationship with the resistances of the said LED lamp module 35, so that the control center will be able to accurately control each individual LED lamp module without particularly recording the corresponding information related to the location and address allocated for each LED lamp module 35 in advance.

The advantages of the present invention are as follows:

1. The circuit module device with addresses generated by method of divided voltage provided in accordance with the present invention can dynamically generate specific addresses by way of detecting the voltage value on relevant nodes;

2. The circuit module device with addresses generated by method of divided voltage provided in accordance with the present invention need not to pre-write any address at all, it can be executed in a very flexible way, that is, the corresponding addresses can be generated only after the completion of the configuration operation for relevant circuit modules; and

3. Upon the application of the light strings, there is no need at all for the control center of the circuit module device with addresses generated by method of divided voltage provided in accordance with the present invention to record the allocated address along with corresponding information of its allocated address for each LED lamp module, and in this way, not only its installation operation will become much more easier, but also it can save a lot of hardware costs without extra memory spaces.

From the foregoing description, it can be found that the circuit module device with addresses generated by method of divided voltage provided in accordance with the present invention is able to dynamically generating specific addresses with a novel, advanced and practical method, whereas, all modifications and changes including various applications, different designs for the circuit module, such as, using different types of circuit modules, connecting more additional sets of circuit modules or even to generate addresses through various algorithm etc., any similar structure consisting of a plurality of circuit modules and to generate specific addresses by way of different node voltage values created by resistances with varied divided voltage for the said circuit modules may be made without departing from the scope of the present invention at all.

Although the present invention has been described with reference to the preferred embodiment that can be achieved easily by a skillful person familiar with this particular technology thereof, it is apparent to those skilled in the art that a variety of modifications and changes may be made without departing from the scope of the present invention which is intended to be defined by the appended claims.

What is claimed is:

1. A circuit module device with address generated by method of divided voltage, which comprises:
a plurality of resistances, which are being electrically connected all together in series;
a plurality of circuit modules, wherein, each circuit module comprises one control unit and one Analog-to-Digital Converter (ADC); and thereat, the said control unit is being electrically connected to the said ADC, and the said ADC contains one Analog-to-Digital Converter (ADC) input end; and moreover, the ADC input ends of a plurality of said circuit modules are being electrically connected to the corresponding a plurality said resistances so as to make an area between the ADC input ends of two adjacent circuit modules being electrically connected with one resistance; and
wherein, a plurality of said circuit modules comprise at least one primary circuit module, one secondary circuit module and one third circuit module; also a plurality of said resistances comprise at least one primary resistance and one secondary resistance; and thereat, the said primary resistance is connected to the said secondary resistance in series, also the said primary resistance is being electrically connected to a position between the ADC input ends of the said primary circuit module and the said secondary circuit module; and the secondary resistance is being electrically connected to a position between the ADC input ends of the said secondary circuit module and the said third circuit module; and thereby, the said primary circuit module, the said secondary circuit module and the said third circuit module is able to convert, via Analog-to-Digital Converter (ADC), individual voltage value on the ADC input end into digital signal respectively, and in addition, while corresponding to different voltage value of said digital signal, while corresponding to different voltage value of said digital signal, the control unit of the said primary circuit module, the said secondary circuit module and the said third circuit module will generate different addresses and thus it will sucessfully complete the addressing operation for a plurality of said circuit modules accordingly.

2. A circuit module device with addresses generated by method of divided voltage as claimed in claim 1, wherein, each circuit module of a plurality of said circuit modules further comprises one memory unit, and all relevant addresses generated by the control unit of each circuit module will be stored in the said memory.

3. A circuit module device with addresses generated by method of divided voltage as claimed in claim 1, wherein, it also include one grounding, and the ADC input end of the said primary circuit module is being electrically connected to the said grounding.

4. A circuit module device with addresses generated by method of divided voltage as claimed in claim 1, wherein, it further contains one grounding being electrically connected to the ADC input end of the said primary circuit module.

5. A circuit module device with addresses generated by method of divided voltage as claimed in claim 1, wherein, each circuit module of a plurality of said circuit modules further comprises one signal input end, and thereat, the signal input ends of a plurality of said circuit modules are being electrically connected all together; moreover, one addressing command can be transferred to a plurality of said circuit modules through the said signal input end to drive as well as control the addressing operation executed by a plurality of said circuit modules.

6. A circuit module device with addresses generated by method of divided voltage as claimed in claim 1, wherein, a plurality of said circuit modules are a plurality of LED lamp modules.

7. A circuit module device with addresses generated by method of divided voltage as claimed in claim 6, wherein, each LED lamp module of a plurality of said LED lamp modules comprises one red light-emitting diode, one green light-emitting diode and one blue light-emitting diode, and also the said control unit is being electrically connected to the said red light-emitting diode, the said green light-emitting diode and the said blue light-emitting diode respectively, so that it will be able to control either the said red light-emitting diode, the said green light-emitting diode or the said blue light-emitting diode making it illuminating, flashing or changing colors.
